(19) United States
(12) Patent Application Publication
(10) Pub. No.: US 2020/0185241 A1
(43) Pub. Date: Jun. 11, 2020

(54) CUTTING APPARATUS AND WAFER PROCESSING METHOD USING CUTTING APPARATUS

(71) Applicant: DISCO CORPORATION, Tokyo (JP)

(72) Inventor: Toshitaka KUNITAKE, Tokyo (JP)

(21) Appl. No.: 16/710,701

(22) Filed: Dec. 11, 2019

(30) Foreign Application Priority Data
Dec. 11, 2018 (JP) 2018-231861

(51) Int. Cl. H01L 21/67; H01L 21/687; H01L 21/02; H01L 21/66; G06T 7/00

(52) U.S. Cl. CPC H01L 21/67288; H01L 21/67092; H01L 21/68764; G06T 2207/30148; H01L 22/12; G06T 7/0004; H01L 21/02021

(57) ABSTRACT

A cutting apparatus includes a cutting unit cutting an outer peripheral edge of a wafer to form an annular groove; a holding section holding the wafer in a rotatable manner; a line scan camera having imaging elements arranged in a row along a width direction of the annular groove so as to face the annular groove of the wafer held by the holding section and capturing the annular groove while rotating the holding section to output a signal; an inspection section obtaining an image of the annular groove corresponding to an entire circumference of the wafer from the signal output by the line scan camera and detecting a width of the annular groove and a chipping from the formed image; and a warning section sending warning information in a case in which an inspection result of the inspecting section is out of an allowable range registered in advance.

### BACKGROUND OF THE INVENTION

### Field of the Invention

The present invention relates to a cutting apparatus and a wafer processing method using the cutting apparatus.

### Description of the Related Art

In recent years, along with demands for reducing in weight, size, and thickness of electronic equipment, a semiconductor wafer on which semiconductor devices are formed (referred to as a wafer hereinafter) has been made thinner. This type of wafer has an outer peripheral edge chamfered in an R shape from a front surface to a back surface. Accordingly, when the back surface of such wafer is ground to be thinned, the outer peripheral edge becomes a so-called knife edge state, causing a chipping in the outer peripheral edge of the wafer during grinding. In order to solve this problem, there has been developed an edge trimming technique in which an annular groove is formed in advance along the outer peripheral edge of the wafer on the front surface of the wafer on which the devices are formed (see, for example, Japanese Patent Laid-Open No. 2007-152906).

However, in this type of edge trimming technique, unless the outer peripheral edge of the wafer is removed at a predetermined width, the R-shape may remain on the outer peripheral edge of the wafer. Thus, a cutting apparatus provided with a function of detecting a width of such an annular groove in the outer peripheral edge of the wafer has been conceived (see, for example, Japanese Patent Laid-Open No. 2013-149822).

### SUMMARY OF THE INVENTION

However, in the conventional technique, the annular groove in the outer peripheral edge of the wafer has been captured at an interval of a predetermined angle by use of an imaging unit. Then, it has been inspected whether or not the width of the annular groove is large enough on the basis of the captured images obtained. In accordance with this technique, a predetermined point on the outer peripheral edge of the wafer needs to be positioned below the imaging unit at every angle, thereby requiring longer time for the inspection. Moreover, since the images are captured at each predetermined angle, the annular groove cannot be inspected all over the circumference. Hence, improvement of an inspection efficiency has been demanded.

It is therefore an object of the present invention to provide a cutting apparatus achieving improvement of an inspection efficiency regarding an annular groove formed along an entire circumference of an outer peripheral edge of a wafer and provide a wafer processing method using the cutting apparatus.

In accordance with an aspect of the present invention, there is provided a cutting apparatus including: a cutting unit having a spindle with a cutting blade mounted thereon and cutting an outer peripheral edge of a wafer to form an annular groove; a holding section holding the wafer in a rotatable manner; a line scan camera having light receiving elements arranged in a row along a width direction of the annular groove so as to face the annular groove of the wafer held by the holding section and capturing the annular groove while rotating the holding section to output a signal; an inspection section forming an image of the annular groove corresponding to an entire circumference of the wafer from the signal output by the line scan camera and detecting a width of the annular groove and a chipping from the formed image; and a warning section sending warning information in a case in which an inspection result of the inspecting section is out of an allowable range registered in advance.

Preferably, the holding section may include a plurality of edge clamps.

Preferably, the holding section may include a chuck table.

In accordance with another aspect of the present invention, there is provided a cutting method of cutting an outer peripheral edge of a wafer with a chamfered portion extending from a front surface of the wafer to a back surface of the wafer formed in the outer peripheral edge by using a cutting apparatus including a cutting unit having a spindle with a cutting blade mounted thereon and cutting the outer peripheral edge of the wafer to form an annular groove, a holding section holding the wafer in a rotatable manner, a line scan camera having light receiving elements arranged in a row along a width direction of the annular groove so as to face the annular groove of the wafer held by the holding section and capturing the annular groove while rotating the holding section to output a signal, an inspection section forming an image of the annular groove corresponding to an entire circumference of the wafer from the signal output by the line scan camera and detecting a width of the annular groove and a chipping from the formed image, and a warning section sending warning information in a case in which an inspection result of the inspecting section is out of an allowable range registered in advance. The cutting method includes: a circular shape cutting step of holding the wafer on a holding surface, causing the cutting blade to cut in the outer peripheral edge of the wafer with the holding section being rotated, and forming the annular groove in the outer peripheral edge; a capturing step of positioning the line scan camera at such a position that the line scan camera faces the annular groove of the wafer held by the holding section holding the wafer in a rotatable manner, causing the holding section to rotate while capturing the wafer, and capturing the entire circumference of the outer peripheral edge of the wafer to thereby obtain an captured image, after the circular shape cutting step is carried out; and an inspecting step of inspecting the captured image in the capturing step in the inspecting section, and sending warning information in a case in which the inspection result of the inspection section is out of the allowable range registered in advance.

According to the present invention, it is possible to capture the annular groove corresponding to the entire circumference of the outer peripheral edge of the wafer while rotating the holding section in a short period of time by use of the line scan camera. Accordingly, the annular groove can be efficiently inspected all over the circumference of the wafer.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view illustrating an example of a cutting apparatus according to a preferred embodiment of the present invention;

FIG. 2 is a cross-sectional view illustrating a chuck table holding a wafer;

FIG. 3 is a plan view schematically illustrating edge clamps holding an outer peripheral edge of the wafer and a line scan camera capturing the outer peripheral edge;

FIG. 4 is a flow chart indicating a procedure of a wafer processing method according to the preferred embodiment;

FIG. 5 is a cross-sectional side view illustrating a circular shape cutting step in the wafer processing method according to the preferred embodiment;

FIG. 6 is a cross-sectional side view illustrating a cleaning step in the wafer processing method according to the preferred embodiment;

FIG. 7 is a cross-sectional side view illustrating a capturing step in the wafer processing method according to the preferred embodiment;

FIG. 8 is a view illustrating an example of a capturing region in the capturing step; and

FIG. 9 is a view illustrating an example of an image corresponding to an entire circumference of the outer peripheral edge of the wafer, the image being formed from a plurality of pieces of image information obtained by capturing.

### DETAILED DESCRIPTION OF THE PREFERRED EMBODIMENT

A preferred embodiment of the present invention will be described in detail below with reference to the attached drawings. The present invention is not limited to contents described in the following embodiment. In addition, the components used in this preferred embodiment may include those that can be easily assumed by persons skilled in the art or substantially the same elements as those known in the art. Moreover, the configurations described below may be suitably used in combination. Further, the configurations may be variously omitted, replaced, or changed without departing from the scope of the present invention.

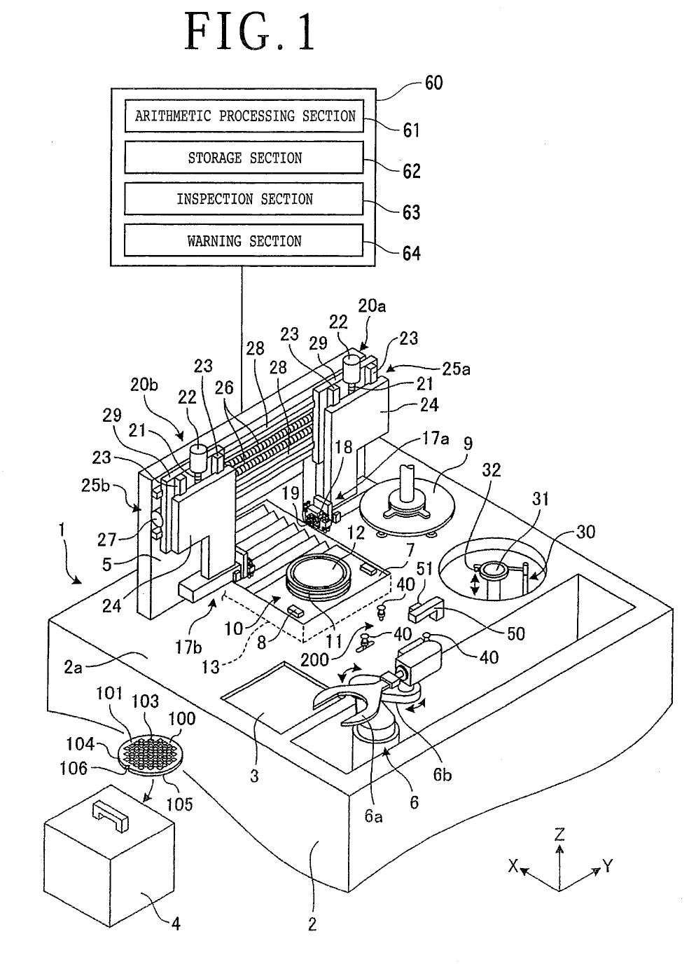

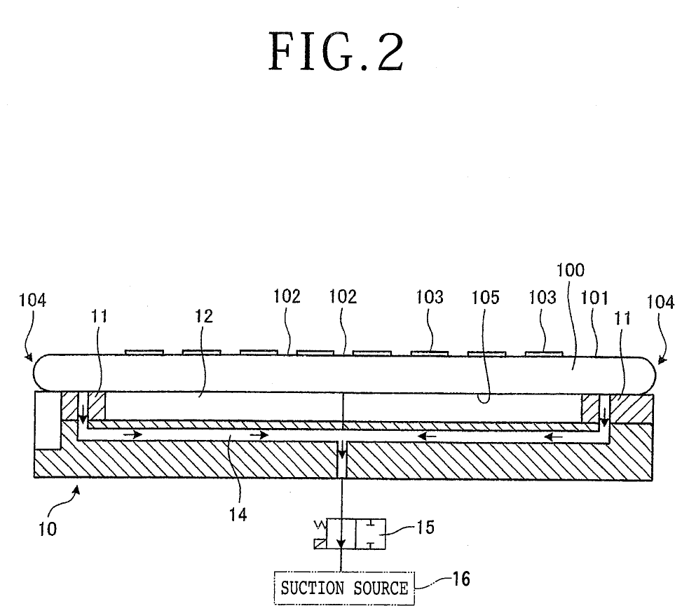

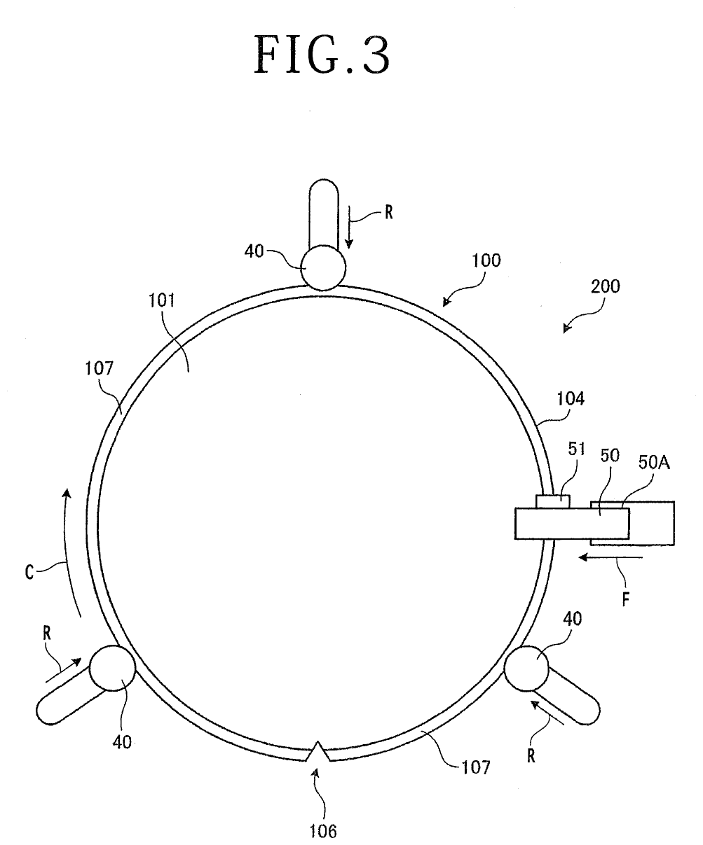

A cutting apparatus according to the preferred embodiment will be described in accordance with the drawings. FIG. 1 is a perspective view illustrating an example of a cutting apparatus according to the preferred embodiment of the present invention. FIG. 2 is a cross-sectional view illustrating a chuck table holding a wafer. FIG. 3 is a plan view schematically illustrating edge clamps holding an outer peripheral edge of the wafer and a line scan camera capturing the outer peripheral edge. Note that, in FIG. 3, devices formed on a front surface of the wafer, and other components are omitted.

A wafer 100 is, for example, a disc-shaped semiconductor device wafer or an optical device wafer formed of silicon, sapphire, silicon carbide (SiC), or gallium arsenide, for example, as a base material. As illustrated in FIGS. 1 and 2, the wafer 100 has a plurality of division lines 102 formed in a grid pattern on an upper surface (front surface) 101 thereof, and the plurality of division lines 102 define a plurality of separate regions each of which has a device such as an integrated circuit (IC) or a large-scale integration (LSI) formed therein. Also, as illustrated in FIG. 2, an outer peripheral edge 104 of the wafer 100 is chamfered into a circular arc shape (R shape) from the upper surface 101 to a lower surface (back surface) 105. Part of the outer peripheral edge 104 of the wafer 100 has a notch 106 formed therein, as an identification mark of crystal orientation.

A cutting apparatus 1 according to this embodiment is an apparatus forming an annular groove along the outer peripheral edge 104 on the upper surface 101 side of the outer peripheral edge 104 of the wafer 100 which is chamfered (edge trimming processing) and including a function of inspecting whether or not a width of the annular groove formed is in a predetermined reference range. As illustrated in FIG. 1, the cutting apparatus 1 includes an apparatus main body 2, and a cassette mounting stage 3 on an upper surface 2a of the apparatus main body 2. The cassette mounting stage 3 can be raised and lowered, and a cassette 4 housing a plurality of the wafers 100 can be placed on this cassette mounting stage 3.

A transfer robot 6 loading and unloading the wafer 100 with respect to the cassette 4 is provided on a front side in an X-axis direction of the apparatus main body 2. The transfer robot 6 includes a robot hand 6a holding the wafer 100, and an arm portion 6b moving the robot hand 6a to a desired position. The transfer robot 6 is movable in a Y-axis direction by a transfer mechanism not illustrated.

A moving table 7 movable in the X-axis direction is provided at a rear side of the X-axis direction on the upper surface 2a of the apparatus main body 2. A double column type frame 5 is erected at a rear side of the X-axis direction on the upper surface 2a of the apparatus main body 2 so as to stride a path of this moving table 7. The moving table 7 includes dressing board holding means 8, a chuck table (holding section) 10, and a processing-feed mechanism 13. The dressing board holding means 8 holds a dressing board for dressing a tip shape of a cutting blade 18 to be flat, which is described later. The chuck table 10 holds the wafer 100 and is rotatable about its own axis. The processing-feed mechanism 13 feeds the chuck table 10 in the X-axis direction.

The chuck table 10 has an annular holding surface 11 holding the outer peripheral edge 104 side of the lower surface 105 of the wafer 100 at an outer peripheral edge thereof. As illustrated in FIG. 2, a region inside the holding surface 11 has a space 12 in a recessed shape which is not in contact with the lower surface 105 of the wafer 100. The chuck table 10 has a suction port 14 formed therein, the suction port 14 being opened to the holding surface 11. The suction port 14 is connected with a suction source 16 through a valve 15. The processing feed mechanism 13 includes a known ball screw provided in a rotatable manner about its axis, a known motor rotating the ball screw about the axis, and a pair of known guide rails supporting the chuck table 10 in a movable manner in the X-axis direction, which are not illustrated.

Also, as illustrated in FIG. 1, the cutting apparatus 1 includes a pair of cutting units 17a and 17b each cutting the outer peripheral edge 104 of the wafer 100 held on the chuck table 10. These cutting units 17a and 17b are disposed to be opposed to each other with the chuck table 10 interposed therebetween. The cutting unit 17a includes at least the cutting blade 18 cutting the upper surface 101 of the wafer 100 along the outer peripheral edge 104 to form an annular groove 107 which is described later in the outer peripheral edge 104, and a spindle 19 having an axis in the Y-axis direction and rotating the cutting blade 18. The cutting unit 17b also has a similar configuration to the cutting unit 17a. Note that the two cutting units 17a and 17b may not be operated simultaneously when the wafer 100 is cut. Alternatively, the cutting units 17a and 17b can be operated simultaneously.

On the front side of the double column type frame 5 in the X-axis direction, there are provided a cutting-feed mechanism 20a cutting-feeding the cutting unit 17a in the Z-axis direction, an indexing-feed mechanism 25a indexing-feeding the cutting unit 17a in the Y-axis direction, a cutting-feed mechanism 20b cutting-feeding the cutting unit 17b in the Z-axis direction, an indexing-feed mechanism 25b indexing-feeding the cutting unit 17b in the Y-axis direction. The cutting-feed mechanism 20a includes a ball screw 21 extending in the Z-axis direction, a motor 22 connected to one end of the ball screw 21, a pair of guide rails 23 extending in parallel to the ball screw 21, an elevating plate 24 coupled with the cutting unit 17a. The pair of guide rails 23 is slidably in connect with one face of the elevating plate 24, and the ball screw 21 is screwed into a nut (not illustrated) formed at a central portion of the elevating plate 24. Then, the motor 22 rotates the ball screw 21, so that the cutting unit 17a can be raised and lowered in the Z-axis direction at a predetermined feed speed with the elevating plate 24. Note that, since the cutting-feed mechanism 20b has a similar configuration to the cutting-feed mechanism 20a, each component constituting the cutting-feed mechanism 20b is denoted by the same reference symbol, and the description thereof is omitted.

The indexing-feed mechanism 25a includes a ball screw 26 extending in the Y-axis direction, a motor 27 (not illustrated) connected to the ball screw 26, a pair of guide rails 28 extending in parallel to the ball screw 26 and being shared with the indexing-feed mechanism 25b, a moving plate 29 with which the cutting-feed mechanism 20a is coupled and moving the cutting unit 17a in the Y-axis direction. Similarly, the indexing-feed mechanism 25b includes a ball screw 26 extending in the Y-axis direction, a motor 27 connected to the ball screw 26, the pair of guide rails 28 described above, a moving plate 29 with which the cutting-feed mechanism 20b is coupled and moving the cutting unit 17b in the Y-axis direction. The pair of guide rails 28 is slidably in contact with the other face of each moving plate 29, and each ball screw 26 is screwed into a nut (not illustrated) formed at a central portion of each moving plate 29. When the ball screw 26 is driven by the motor 27 and rotated, each of the cutting units 17a and 17b can be indexing-fed in the Y-axis direction with the moving plate 29.

In the cutting apparatus 1, there are disposed a cleaning unit 30 cleaning the wafer 100 after being processed, and a transfer pad 9 transferring the wafer 100 after being processed to the cleaning unit 30 from the chuck table 10. The cleaning unit 30 includes at least a spinner table 31 and a cleaning water nozzle 32. The spinner table 31 holds the wafer 100 and is rotated about its own axis in such a manner that the spinner table 31 can be raised and lowered. The cleaning water nozzle 32 supplies cleaning water to the wafer 100 held on the spinner table 31.

At a central portion of the upper surface 2a of the apparatus main body 2, an inspection region 200 in which a width (groove width) of an annular groove formed in the outer peripheral edge of the wafer 100 is inspected is provided between the cassette mounting stage 3 and the cleaning unit 30. In this inspection region 200, the cutting apparatus 1 includes a plurality of (at least three) edge clamps (holding portions) 40, and a line scan camera 50. The edge clamps 40 clamp (hold) the outer peripheral edge 104 of the wafer 100. The line scan camera 50 captures the annular groove 107 which is formed in the outer peripheral edge 104 of the processed wafer 100 held by the edge clamps 40.

All or any of the plurality of edge clamps 40 are provided in the vicinity of the outer peripheral edge 104 of the wafer 100 so as to be movable in a radial direction R, as illustrated in FIG. 3. Also, the edge clamps 40 are formed into a substantially cylindrical shape, and each central portion thereof in a height direction is recessed in a laterally facing V-shape in a circumferential direction C (horizontal direction). Moreover, the edge clamps 40 are each supported on the upper surface 2a of the apparatus main body 2 in such a manner as to be freely rotation-driven in a horizontal plane. The edge clamps 40 can clamp the outer peripheral edge 104 in a point-contact state regardless of a thickness of the wafer 100. Accordingly, the edge clamps 40 can hold the wafer 100 so as to be rotatable in the circumferential direction C with the outer peripheral edge 104 of the wafer 100 clamped therewith.

As illustrated in FIG. 3, the line scan camera 50 includes a long thin casing 50A disposed above the wafer 100 so as to face the annular groove 107 of the outer peripheral edge 104. A longitudinal direction F of this casing 50A extends along the radial direction R of the wafer 100 held with the edge clamps 40. In the longitudinal direction F of the casing 50A, a plurality of imaging elements (light receiving elements) 50B (see FIG. 7) such as a plurality of charge-coupled devices (CCDs) or complementary metal-oxide semiconductor (CMOS) image sensors are incorporated side-by-side in a row. Accordingly, the plurality of imaging elements 50B of the line scan camera 50 are arranged along a width direction of the annular groove 107 of the wafer 100, and the line scan camera 50 captures the annular groove 107 of the wafer 100 for each one line while rotating the wafer 100 held with the edge clamps 40. The line scan camera 50 used herein has a longitudinal length larger than the width of the annular groove 107 of the wafer 100. In addition, the line scan camera 50 is movable back and forth in the radial direction R described above. Accordingly, the line scan camera 50 extends above the annular groove 107 of the wafer 100 in capturing and preferably retracts from a position above the wafer 100 when the wafer 100 is gripped with or detached from the edge clamps 40. Further, the line scan camera 50 includes a light source 51 illuminating the annular groove 107 in capturing. A plurality of pieces of image information (signals) obtained by capturing by the line scan camera 50 are output to a control unit 60 included in the cutting apparatus 1.

As illustrated in FIG. 1, the control unit 60 includes an arithmetic processing section 61, a storage section 62, an inspection section 63, and a warning section 64. The arithmetic processing section 61 includes a microprocessor such as a central processing unit (CPU) and executes a computer program to generate various types of control signals for controlling an operation of the cutting apparatus 1 and an inspection operation with respect to the annular groove 104. The control signals thus generated are output to each component of the cutting apparatus 1 through an input/output interface, not illustrated. The storage section 62 stores various pieces of information, particularly the pieces of image information output from the line scan camera 50. The line scan camera 50 captures the annular groove 107 all over the circumference of the outer peripheral edge 104 of the wafer 100 being rotated, and in order to successively output these pieces of image information, the storage section 62 stores at least the pieces of image information corresponding to the entire circumference of the outer peripheral edge 104.

The inspection section 63 forms an image corresponding to the entire circumference of the outer peripheral edge 104 of the wafer 100 from the pieces of image information stored in the storage section 62 under control of the arithmetic processing section 61. Further, the inspection section 63 inspects a width of the annular groove 107, presence or absence of a chipping in a region of the annular groove 107, and a size of the chipping. The warning section 64 compares the width of the annular groove 107 and the size of the chipping which have been inspected in the inspection section 63 with an allowable range registered in advance. Then, the warning section 64 determines that the processing is normally carried out if the width of the annular groove 107 and the size of the chipping are in the allowable range. Conversely, the warning section 64 determines that the processing is not normally carried out if the width of the annular groove 107 and the size of the chipping are out of the allowable range and sends warning information under control of the arithmetic processing section 61. As the warning information, for example, warning may be made by lighting up a warning lamp, or sounding a warning alarm. Alternatively, a message indicating abnormal processing may be displayed on an operation panel included in the cutting apparatus 1.

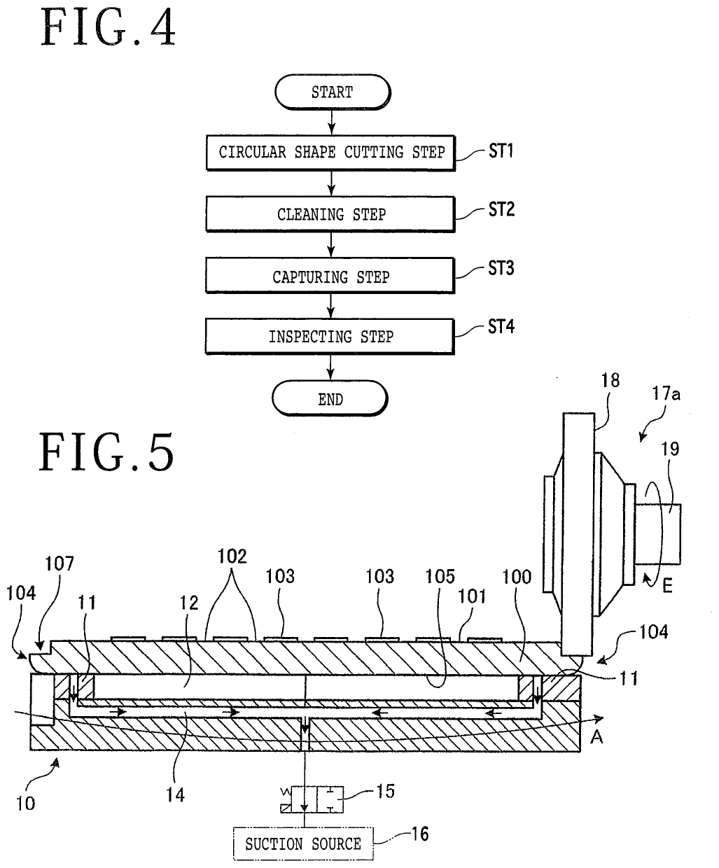

Next, a method of processing the wafer 100 by use of the cutting apparatus 1 described above will be described. FIG. 4 is a flow chart indicating a procedure of a wafer processing method according to the preferred embodiment. In the wafer processing method according to this embodiment, the annular groove 107 is formed in the outer peripheral edge 104 of the wafer 100, and the annular groove 107 formed is inspected. As described in FIG. 4, the wafer processing method includes a circular shape cutting step ST1, a cleaning step ST2, a capturing step ST3, and an inspecting step ST4. (

### Circular Shape Cutting Step

FIG. 5 is a cross-sectional side view illustrating the circular shape cutting step ST1. In the circular shape cutting step ST1, the outer peripheral edge 104 of the wafer 100 held on the chuck table 10 is cut in with the cutting blade 18 while the chuck table 10 is being rotated to thereby form the annular groove 107 in the outer peripheral edge 104. In this embodiment, a case in which the annular groove 107 is formed only with the cutting unit 17a will be described.

First, the wafer 100 is held on the chuck table 10. In this case, using the transfer robot 6 illustrated in FIG. 1, the wafer 100 before being processed is taken out from the cassette 4, and the lower surface 105 of this wafer 100 is placed on the holding surface 11 of the chuck table 10. Subsequently, the valve 15 illustrated in FIG. 2 is opened to apply a suction force of the suction source 16 to the holding surface 11, and accordingly, the wafer 100 is held under suction on the holding surface 11. At this time, since the lower surface 105 of the wafer 100 facing the space 12 is in a non-contact state, there is no possibility that dust or the like is attached to the lower surface 105 of the wafer 100.

When the wafer 100 is held on the chuck table 10, the moving table 7 (see FIG. 1) is used to move the chuck table 10 below the cutting unit 17a. Then, as illustrated in FIG. 5, the annular groove 107 is formed in the outer peripheral edge 104 of the wafer 100. More specifically, the chuck table 10 which has been moved below the cutting unit 17a is rotated in a direction indicated with an arrow A, for example. The cutting unit 17a rotates the spindle 19 to thereby rotate the cutting blade 18 in a direction indicated with an arrow E at a predetermined rotational speed, for example, while causing the cutting-feed mechanism 20a (see FIG. 1) to lower the cutting unit 17a in the Z-axis direction, so that the rotating cutting blade 18 cuts in the outer peripheral edge 104 of the wafer 100 held on the chuck table 10. In this manner, the chamfered portion formed in a circular arc shape in the outer peripheral edge 104 of the wafer 100 is partly removed by the cutting blade 18, so that the annular groove 107 having a desired width and depth is formed. Note that the cutting unit 17a may be lowered in the Z-axis direction to cause the cutting blade 18 to cut in the outer peripheral edge 104 of the wafer 100. In addition, the cutting unit 17a may be positioned in advance to a predetermined cut-in height before the chuck table 10 is moved in the X-axis direction, and then, cause the cutting blade 18 to cut in the outer peripheral edge 104 of the wafer 100.

### Cleaning Step

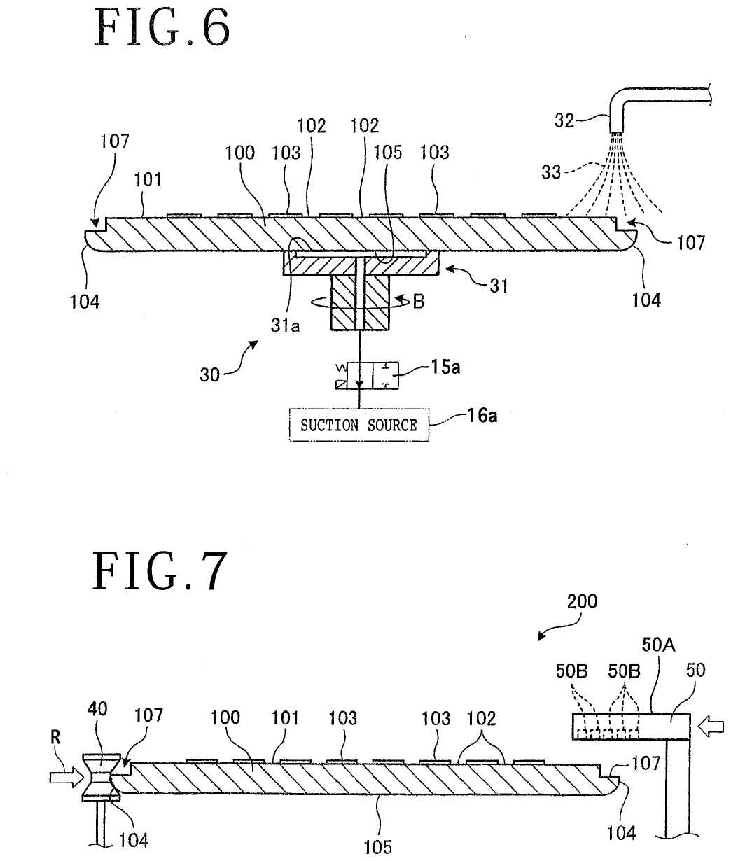

FIG. 6 is a cross-sectional side view illustrating the cleaning step ST2. In the cleaning step ST2, the wafer 100 with the annular groove 107 subjected to cutting processing is cleaned. After the circular shape cutting step ST1 is carried out, the transfer pad 9 transfers the processed wafer 100 from the chuck table 10 to the spinner table 31 of the cleaning unit 30. As illustrated in FIG. 6, after the wafer 100 is placed on the spinner table 31, a valve 15a is opened, so that the wafer 100 is held under suction on a holding surface 31a of the spinner table 31 with a suction force of a suction source 16a. After that, while the spinner table 31 is rotated at a predetermined rotational speed in a direction indicated with an arrow B, for example, cleaning water 33 is supplied from the cleaning water nozzle 32 toward the wafer 100 held on the spinner table 31, and accordingly, the wafer 100 is cleaned. After finishing cleaning the wafer 100, the spinner table 31 is rotated at a higher rotational speed than the speed when cleaning the wafer 100 and a high-pressurized air is supplied, for example, so that the wafer 100 is dried. In the cleaning step ST2, the cleaning water nozzle 32 may be moved above the upper surface (front surface) 101 of the wafer 100 to supply the cleaning water all over the upper surface 101.

### Capturing Step

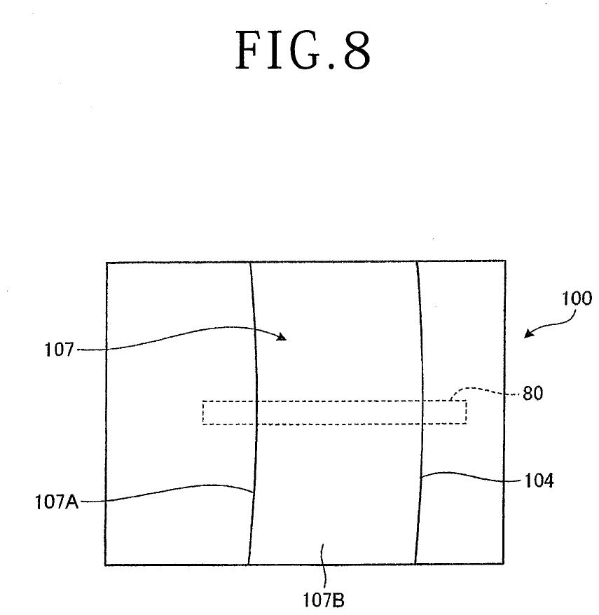

FIG. 7 is a cross-sectional side view illustrating the capturing step ST3. FIG. 8 is a view illustrating an example of a capturing region in the capturing step ST3. In the capturing step or imaging step ST3, the line scan camera 50 captures an image of the annular groove 107 corresponding to the entire circumference of the outer peripheral edge 104 of the wafer 100 while rotating the wafer 100.

After the cleaning step ST2 is carried out, in order to inspect whether or not the annular groove 107 has a desired groove width, the cleaned wafer 100 is unloaded from the spinner table 31 by use of the transfer robot 6, and this wafer 100 is transferred to the inspection region 200. When the wafer 100 is transferred to the inspection region 200, as illustrated in FIG. 3, each of the edge clamps 40 moves so as to reduce in its radial length and then clamps the outer peripheral edge 104 of the wafer 100 to be secured. Moreover, each of the edge clamps 40 rotates to cause the wafer 100 to be rotated in the circumferential direction C in FIG. 3, for example.

Next, as illustrated in FIGS. 3 and 7, the line scan camera 50 is moved in the radial direction R of the wafer 100 to be positioned to face the annular groove 107. While each of the edge clamps 40 is rotation-driven to rotate the wafer 100, the line scan camera 50 captures the annular groove 107 corresponding to the entire circumference of the outer peripheral edge 104 of the wafer 100 until the notch 106 (see FIG. 3) comes back to the original position again in one rotation. The line scan camera 50 includes the plurality of imaging elements 50B arranged in a row in the casing 50A, and these imaging elements 50B are arranged in the radial direction R of the wafer 100. Accordingly, as illustrated in FIG. 8, the line scan camera 50 successively captures the annular groove 107 by each capturing region 80 corresponding to one line of the imaging elements 50B arranged in accordance with the rotation of the wafer 100. This capturing region 80 extends in a radial direction of the annular groove 107 and includes at least a groove bottom 107B between a groove inner circumference edge 107A of the annular groove 107 and the outer peripheral edge 104 of the wafer 100. The image information corresponding to each capturing region 80 is output to the storage section 62, and the storage section 62 stores the pieces of image information corresponding to the entire circumference of the outer peripheral edge 104.

### Inspecting Step

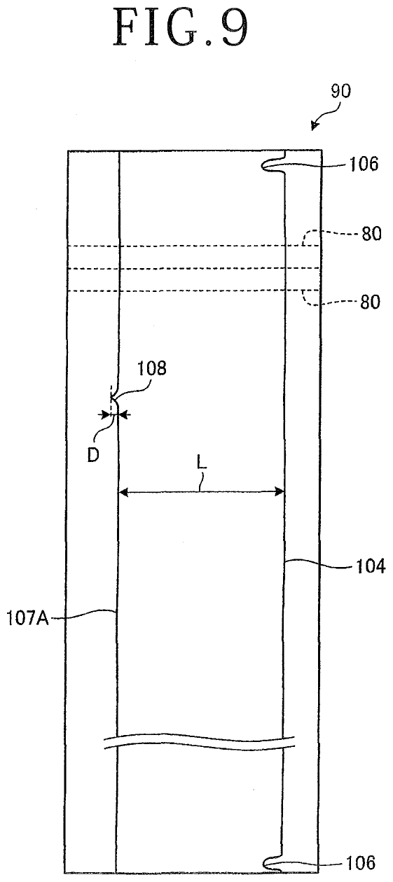

In the inspecting step ST4, an image corresponding to the entire circumference of the outer peripheral edge 104 of the wafer 100 is formed from the pieces of image information stored in the storage section 62, and a width of the annular groove 107, presence or absence of a chipping in the region of the annular groove 107, or a size of the chipping are inspected from the formed image. FIG. 9 is a view illustrating an example of an image corresponding to an entire circumference of the outer peripheral edge of the wafer, the image being formed from a plurality of pieces of image information obtained by capturing. An image 90 corresponding to the entire circumference of the outer peripheral edge 104 of the wafer 100 is formed by connecting the pieces of image information corresponding to the capturing region 80, as illustrated in FIG. 9. The inspection section 63 inspects a width L of the annular groove 107, presence or absence of a chipping 108 in the region of the annular groove 107, or a size D of the chipping 108 on the basis of this image 90. The width L of the annular groove 107 is a radial length thereof between the groove inner circumference edge 107A of the annular groove 107 and the outer peripheral edge 104 of the wafer 100. Also, the chipping 108 in the region of the annular groove 107 is, for example, a lost portion generated in the groove inner circumference edge 107A of the annular groove 107, and the size D of the chipping 108 is a radial length thereof.

The inspection section 63 determines whether or not the width L of the annular groove 107 is in the allowable range registered in advance. More specifically, the inspection section 63 reads a maximum value and a minimum value of the width L of the annular groove 107 of the wafer 100 which are derived from values corresponding to the entire circumference, and determines whether or not the maximum value and the minimum value are each in the allowable range. In addition, the inspection section 63 determines whether or not the chipping 108 is generated in the region of the annular groove 107, and if the chipping 108 is generated, determines whether or not the size D of the chipping 108 is in the allowable range registered in advance. This size D of the chipping 108 may include a length (size) in not only the radial direction R of the wafer 100 (annular groove 107), but also the circumferential direction C.

When determination described above is made in the inspection section 63, in a case in which the width L of the annular groove 107 and the size D of the chipping 108 are out of the allowable range, the warning section 64 determines that the annular groove 107 is not normally processed, and then sends warning information. As the warning information, for example, warning may be made by lighting up a warning lamp, or sounding a warning alarm. Alternatively, a message indicating abnormal processing may be displayed on an operation panel included in the cutting apparatus 1. In a case in which the width L of the annular groove 107 and the size D of the chipping 108 are out of the allowable range, uneven wear may occur in the tip shape of the cutting blade 18. Accordingly, sharpening the tip of the cutting blade 18 is carried out by causing the cutting blade 18 being rotated to cut in the dressing board held on the dressing board holding means 8 illustrated in FIG. 1 for dressing the tip of the cutting blade 18 or for flattening the tip of the cutting blade 18 to adjust the tip shape thereof to be evenly flat. Also, depending on a degree of the uneven wear of the cutting blade 18, the cutting blade 18 may be replaced with a new cutting blade 18.

After the inspecting step ST4 is carried out, the wafer 100 is unloaded from the inspection region 200 by the transfer robot 6, and this wafer 100 is housed in the cassette 4. Note that, in a case in which the inspecting step ST4 is carried out and the wafer 100 is determined that the width L of the annular groove 107 and the size D of the chipping 108 are out of the allowable range, the storage section 62 of the cutting apparatus 1 stores the information regarding which stage of the cassette 4 the wafer 100 is housed in, as a defective wafer. In addition, the storage section 62 can store each location of the width L of the annular groove 107 and the size D of the chipping 108 which have been out of the allowable range with reference to the notch 106. Moreover, the wafer 100 with the width L of the annular groove 107 and the size of the chipping 108 being out of the allowable range may be housed in another cassette different from the cassette 4 in which the wafer 100 has been originally housed.

As described above, the cutting apparatus 1 according to the preferred embodiment includes the pair of cutting units 17a and 17b, the edge clamps 40, the line scan camera 50, the inspecting section 63, and the warning section 64. More specifically, the pair of cutting units 17a and 17b has the spindle 19 with the cutting blade 18 mounted thereon and cuts the outer peripheral edge 104 of the wafer 100 to form the annular groove 107. The edge clamps 40 hold the wafer 100 in a rotatable manner. The line scan camera 50 has the imaging elements 50B arranged in a row such that the imaging elements 50B face the annular groove 107 of the wafer 100 held with the edge clamps 40 and are disposed along the width direction of the annular groove 107 and captures the annular groove 107 while rotating the edge clamps 40 horizontally, to thereby output the signals. The inspecting section 63 forms the image 90 of the annular groove 107 corresponding to the entire circumference of the outer peripheral edge 104 of the wafer 100 from the signal output by the line scan camera 50 which has captured the annular groove 107, and detects the width L of the annular groove 107, presence or absence of the chipping 108, and the size D thereof from the image 90. The warning section 64 sends the warning information in a case in which the inspection result of the inspecting section 63 is out of the allowable range registered in advance. With this configuration, by capturing the annular groove 107 with use of the line scan camera 50, it is possible to capture the annular groove 107 corresponding to the entire circumference of the outer peripheral edge 104 of the wafer 100 while rotating the edge clamps 40 in a short period of time. Accordingly, the annular groove 107 can be efficiently inspected all over the circumference of the wafer 100.

According to an experiment by the present inventor, in the case of capturing the annular groove 107 at predetermined angular intervals at a plurality of locations (36 capturing points, for example) with use of a conventional area camera, it was required to position each predetermined capturing point below the area camera each time, thereby requiring 150 seconds to capture the 36 capturing points. Moreover, in this conventional configuration, since the capturing was carried out for each predetermined angular interval, the annular groove 107 corresponding to the entire circumference of the outer peripheral edge 104 was not able to be inspected. In contrast, according to the configuration of the present embodiment using the line scan camera 50, it became clear that, in a case in which the wafer 100 is rotated at a predetermined speed (5 mm/s) with use of the edge clamps 40, it is possible to capture the annular groove 107 corresponding to the entire circumference of the outer peripheral edge 104 for 12.6 seconds which is 1/10 or shorter in time than the conventional configuration.

Accordingly, since it is possible to easily and quickly detect whether or not the wafer 100 is defective by determining whether or not the width L of the annular groove 107 and the size D of the chipping 108 are in the allowable range for each of the wafers 100, productivity of a finished product can be more enhanced.

Note that the present invention is not limited to the foregoing embodiment. In other words, various changes and modifications may be made therein without departing from the scope of the present invention. For example, in the foregoing embodiment, the entire circumference of the outer peripheral edge 104 of the wafer 100 is captured by the line scan camera 50 in a state in which the wafer 100 is rotated with the edge clamps 40. However, as an alternative example, it may be configured that the line scan camera 50 moves to face the annular groove 107 of the wafer 100 with the wafer 100 held on the chuck table (holding section) 10.

More specifically, it may be configured that, after carrying out the circular shape cutting step ST1 in which the annular groove 107 is formed in the outer peripheral edge 104 of the wafer 100 by use of the cutting units 17a and 17b, the line scan camera 50 is moved so as to face the annular groove 107 of the wafer 100 in a state in which the chuck table 10 (the wafer 100 held thereon) is rotated, without moving the wafer 100, to capture the entire circumference of the outer peripheral edge 104 of the wafer 100. According to this configuration, the wafer 100 can be inspected on the chuck table 10 right after the cutting without moving the wafer 100, so that the time efficiency for the inspection is excellent.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A cutting apparatus comprising:
a cutting unit having a spindle with a cutting blade mounted thereon and cutting an outer peripheral edge of a wafer to form an annular groove;
a holding section holding the wafer in a rotatable manner;
a line scan camera having light receiving elements arranged in a row along a width direction of the annular groove so as to face the annular groove of the wafer held by the holding section and capturing the annular groove while rotating the holding section to output a signal;
an inspection section forming an image of the annular groove corresponding to an entire circumference of the wafer from the signal output by the line scan camera and detecting a width of the annular groove and a chipping from the formed image; and
a warning section sending warning information in a case in which an inspection result of the inspecting section is out of an allowable range registered in advance.

2. The cutting apparatus according to claim 1,
wherein the holding section includes a plurality of edge clamps.

3. The cutting apparatus according to claim 1,
wherein the holding section includes a chuck table.

4. A cutting method of cutting an outer peripheral edge of a wafer with a chamfered portion extending from a front surface of the wafer to a back surface of the wafer formed in the outer peripheral edge by using a cutting apparatus including:
a cutting unit having a spindle with a cutting blade mounted thereon and cutting the outer peripheral edge of the wafer to form an annular groove,
a holding section holding the wafer in a rotatable manner,
a line scan camera having light receiving elements arranged in a row along a width direction of the annular groove so as to face the annular groove of the wafer held by the holding section and capturing the annular groove while rotating the holding section to output a signal,
an inspection section forming an image of the annular groove corresponding to an entire circumference of the wafer from the signal output by the line scan camera and detecting a width of the annular groove and a chipping from the formed image, and
a warning section sending warning information in a case in which an inspection result of the inspecting section is out of an allowable range registered in advance,
the cutting method comprising:
a circular shape cutting step of holding the wafer on a holding surface, causing the cutting blade to cut in the outer peripheral edge of the wafer with the holding section being rotated, and forming the annular groove in the outer peripheral edge;
a capturing step of positioning the line scan camera at such a position that the line scan camera faces the annular groove of the wafer held by the holding section holding the wafer in a rotatable manner, causing the holding section to rotate while capturing the wafer, and capturing the entire circumference of the outer peripheral edge of the wafer to thereby obtain an captured image, after the circular shape cutting step is carried out; and
an inspecting step of inspecting the captured image in the capturing step in the inspecting section, and sending warning information in a case in which the inspection result of the inspection section is out of the allowable range registered in advance.
